(19) United States
(12) Patent Application Publication
(10) Pub. No.: US 2008/0024162 A1
(43) Pub. Date: Jan. 31, 2008

(54) CONSTANT IMPEDANCE CMOS OUTPUT BUFFER

(75) Inventors: Amit Kumar Rathi, Madhya Pradesh (IN); Ankit Srivastava, Uttar Pradesh (IN)

Correspondence Address: STMicroelectronics Inc.;c/o WOLF, GREENFIELD & SACKS, P.C., 600 Atlantic Avenue, BOSTON, MA, 02210-2206, US

(73) Assignee: STMicroelectronics Pvt. Ltd., Greater Noida (IN)

(21) Appl. No.: 11/782,752

(22) Filed: Jul. 25, 2007

(30) Foreign Application Priority Data
Jul. 25, 2006 (IN) 1705/DEL/2006

(51) Int. Cl. H03K 19/0175

(52) U.S. Cl. 326/30

(57) ABSTRACT

The present invention provides a buffer circuit for providing constant impedance to a transmission line in an integrated circuit. The buffer circuit includes an output terminal, an input terminal, a power supply terminal, a virtual voltage terminal, a first switching element, and a second switching element. The input terminal includes a first terminal and a second terminal for receiving a binary logic signal. The first switching element is connected between the output terminal and the power supply terminal. The second switching element is connected between the output terminal and the virtual voltage terminal. The circuit includes switching control logic for turning on and off the first and second switching elements in a complementary manner in response to the binary logic signal. The circuit further includes compensating logic for increasing output impedance to the output terminal. In the buffer circuit a layout of the driver circuit can be easily implemented with an optimized driver area.

### FIELD OF THE INVENTION

This invention relates to a field of semiconductor integrated circuits, and more specifically to an output buffer circuit for improving an output of the integrated circuits during state transitions by providing constant impedance to a transmission line inside the integrated circuit.

### BACKGROUND OF THE INVENTION

An output buffer of an integrated circuit is generally provided for transferring signals from an internal logic circuit, to an output of the integrated circuit. The output of the integrated circuit may be connected to an electrical transmission line. In addition, the far-end of the transmission line may be connected to an input terminal of another integrated circuit. In the context of the communication of digital signals, the varying electrical characteristics of the transmission line, as well as the far-end circuit input, gives rise to a number of problems.

One problem pertains to transmission line effects. If the far-end is improperly terminated and/or open circuit, an impedance mismatch and consequent signal reflections may occur. In the open circuit context, transitions of the output signal generated by the output buffer may result in undershoots and overshoots relative to the desired steady state value. These signal variations may exceed the maximum rated input voltage of any receiving unit to which the transmission line is connected. In addition, the overshoots and undershoots can cross a threshold voltage of the receiver several times. This threshold crossing can result in the generation of system errors (e.g., logic errors).

Moreover, the transmission line has characteristic impedance Zₒ. In addition, a real world output buffer exhibits output impedance, which will be designated generally in this patent application as Rₒ. In practical implementations, the output buffer exhibits a different impedance profile depending on whether its output is transitioning high-to-low or low-to-high.

The degree to which the output buffer impedance matches the transmission line impedance depends on at least two characteristics of the buffer output signal: (i) a so-called “plateau” voltage level, and (ii) the amount of undershoot and overshoot (i.e., ringing). The plateau level refers to an intermediate step exhibited in the near and far end of the transmission line while transitioning. This intermediate step or plateau at near and far end are caused by the impedance mismatch between the transmission line and the output driver. The height of the step or plateau depends on the relative values of Rₒ and Zₒ, and the length or duration of the step depends upon the round trip electrical delay of the output signal along the transmission line. The problem arising, when Rₒ>Zₒ is that the voltage level of the plateau may fail to define either logic high or a logic low (i.e., may be an undefined voltage level). An output signal at this voltage level may generate spurious results at the input of any circuit to which it is connected, typically at the far end of the transmission line, causing system errors as well as causing excessive power dissipation. On the contrary, when Rₒ<Zₒ results in ringing in the output signal, which causes over voltage, threshold crossing, etc. In the case of Rₒ=Zₒ, the half of the supply voltage develops at the near end and this voltage travels down the transmission towards the far end. If the transmission line is open circuited or perfectly terminated with the characteristic impedance of the transmission line, then the same voltage is reflected back with the same polarity. Thus there is no plateau developed at the far end and the signal is transmitted to the receiving device without any overshoot and undershoots with defined logic level.

FIG. 1A illustrates a conventional circuit 16 for the related art. The circuit 16 includes a pull-up circuit 22 includes a PMOS transistor 30, and a pull-down circuit 24 includes NMOS transistor 32. The circuit 16 receives an input data signal PD 26 and ND 27 from the core.

FIG. 1B is a current/voltage (IV) plot of the pull-up circuit 22 of the circuit 16 at an output node 28. The plot shows that a current of the pull up circuit 22 is constant till V_{PAD}=Vₜₚ, but the impedance decreases as V_{DS} of the pull up driver 22 decreases. In this region PMOS transistor 30 is in a saturation region. After V_{PAD}=Vₜₚ the PMOS transistor 30 enters in a linear region. The current of the pull up circuit 22 decreases parabolically in the linear region and V_{DS} of the pull up circuit 22 decreases linearly, since the current is not decreasing at the same rate as the V_{DS}, thus the impedance decreases in this linear region also. As such, the impedance of driver 16 will mismatch the impedance of the transmission line.

FIG. 2A illustrates a conventional circuit for the related art, where a diode connected branch 54 is added in parallel with a normal connected branch 52. A diode connected branch 54 increases output impedance in accordance with an increase in voltage on a node 28.

FIG. 2B illustrates a plot 4 for a normal connected branch 52 and the diode connected branch 54. The current for diode connected branch is given by equation:
I∝(V_{GS}−Vₜₙ)²(1+λV_{GS}); VDS=V_{GS}

Since V_{GS} decreases linearly with a linear increase in node voltage 28 and neglecting (1+λV_{GS}) effect the current plot 2 of branch 54 is almost parabolic for output voltages between zero and Vdde−Vₜₙ. The plot 4 in FIG. 2B for the pull-up transistor 30 of FIG. 2A is parabolic from Vtp to Vdde. The plot 6 for pull-up circuit 22 is the addition of the IV plots for the normal connected branch 52 and the diode connected branch 54. The plot 6 shows that the current is almost linear, thus giving almost a constant impedance to be matched to the transmission line impedance. Although we get almost constant impedance with this architecture, the disadvantage of this architecture is in the layout implementation. Since the branch 54 of the pull up driver uses both NMOS and PMOS connected at node N3. Due to larger device sizes NMOS/PMOS transistors are made in fingers, thus during layout implementation some problems arise during routing to connect the PMOS transistor 20 with the NMOS transistor 26, which could otherwise would have been easily implemented with a shared drain MOS transistors, resulting in a less driver area.

Accordingly, there is a need to provide a matched output buffer that reduces or eliminates one or more of the problems set forth above.

Therefore, there is a need of an output buffer module providing constant output impedance for driving transmission line loads in the integrated circuits. Moreover, the module should further improve the output of the integrated circuits during state transitions.

### SUMMARY OF THE INVENTION

According to one embodiment, the present invention provides an output buffer circuit providing a constant impedance to match the transmission line.

According to another embodiment, the present invention, a buffer circuit providing fabrication flexibility is provided, such that layout of the driver can be easily implemented with an optimized driver area.

In one embodiment, the present invention provides a buffer circuit providing constant impedance to a transmission line in an integrated circuit comprising:

an output terminal for outputting data;

an input terminal having a first terminal and a second terminal for receiving a binary logic signal;

a power supply terminal for providing a high potential;

a virtual voltage terminal for providing a low potential;

a first switching element connected between said output terminal and said power supply terminal, said first switching element comprising:
a first PMOS transistor having a gate terminal connected to said first terminal, its source terminal connected to said power supply terminal, and its drain terminal connected to said output terminal;
a second NMOS transistor having its gate terminal connected to said first terminal through an inverter, a drain terminal connected to said power supply terminal, and a source terminal connected to said output terminal;

a second switching element connected between said output terminal and said virtual voltage terminal, said second switching element comprising:
a third NMOS transistor having a drain terminal connected to said output terminal, a gate terminal connected to said second terminal, and a source terminal connected to said virtual voltage terminal;
a fourth PMOS transistor having a gate terminal connected to said second terminal through an inverter, a source connected to the source of said second NMOS transistor, and a drain connected to said virtual voltage terminal;

switching control means for turning on and off said first and second switching elements in a complementary manner in response to said binary logic signal; and

compensating means for increasing output impedance to said output terminal in response to a voltage at said output terminal approaching a voltage level corresponding to the data to be output upon a change in level of said binary logic signal.

In another embodiment, the present invention provides a buffer circuit providing constant impedance to a transmission line in an integrated circuit comprising:

an output terminal for outputting data;

an input terminal having a first terminal and a second terminal for receiving a binary logic signal;

a power supply terminal for providing a high potential;

a virtual voltage terminal for providing a low potential;

a first switching element connected between said output terminal and said power supply terminal, said first switching element comprising:
a first PMOS transistor having a gate terminal connected to said first terminal, its source terminal connected to said power supply terminal, and its drain terminal connected to said output terminal;
a second NMOS transistor having its gate terminal connected to said first terminal through an inverter, a drain terminal connected to said power supply terminal, and a source terminal connected to a potential terminal;
a third NMOS transistor having its gate terminal connected to said power supply terminal, a drain terminal connected to the source of said second transistor, and a source terminal connected to said output terminal;

a second switching element connected between said output terminal and said virtual voltage terminal, said second switching element comprising:
a fourth NMOS transistor having a drain terminal connected to said output terminal, a gate terminal connected to said second terminal, and a source terminal connected to said virtual voltage terminal;
a fifth PMOS transistor having a gate terminal connected to said virtual voltage terminal, a source terminal connected to the source of said third NMOS transistor, and a drain connected to a potential terminal;
a sixth PMOS transistor having a gate terminal connected to said second terminal through an inverter, a source terminal connected to the drain terminal of said fifth transistor, and a drain terminal connected to said virtual voltage terminal;

switching control means for turning on and off said first and second switching elements in a complementary manner in response to said binary logic signal; and

compensating means for increasing output impedance to said output terminal in response to a voltage at said output terminal approaching a voltage level corresponding to the data to be output upon a change in level of said binary logic signal.

In another embodiment, the present invention provides a buffer circuit providing constant impedance to a transmission line in an integrated circuit comprising:

an output terminal for outputting data;

an input terminal having a first terminal and a second terminal for receiving a binary logic signal;

a power supply terminal for providing a high potential;

a virtual voltage terminal for providing a low potential;

a first switching element connected between said output terminal and said power supply terminal, said first switching element comprising:
a first PMOS transistor having a gate terminal connected to said first terminal, its source terminal connected to said power supply terminal, and its drain terminal connected to said output terminal;
a second NMOS transistor having a gate terminal and a drain terminal connected to said power supply terminal, and a source terminal connected to a potential terminal;
a third NMOS transistor having its gate terminal connected to said first terminal through an inverter, a drain terminal connected to the source of said second NMOS transistor, and a source terminal connected to said output terminal;

a second switching element connected between said output terminal and said virtual voltage terminal, said second switching element comprising:
a fourth NMOS transistor having a drain terminal connected to said output terminal, a gate terminal connected to said second terminal, and a source terminal connected to said virtual voltage terminal;
a fifth PMOS transistor having a gate terminal connected to said second terminal through an inverter, a source connected to the source of said third NMOS transistor, and a drain connected to a potential terminal;
a sixth PMOS transistor having a gate terminal and a drain terminal connected to said virtual voltage terminal, and a source terminal connected to the drain terminal of said fifth transistor;

switching control means for turning on and off said first and second switching elements in a complementary manner in response to said binary logic signal; and

compensating means for increasing output impedance to said output terminal in response to a voltage at said output terminal approaching a voltage level corresponding to the data to be output upon a change in level of said binary logic signal.

In another embodiment, the present invention provides a method of providing constant output impedance to a transmission line in an integrated circuit through a buffer circuit comprising:

connecting an output terminal to a first power supply terminal through a first switching element, when a first logic level signal is applied to an input terminal;

connecting said output terminal to a second power supply terminal through a second switching element, when a second logic level signal is applied to said input terminal; and

increasing impedance in series with said output terminal in response to a voltage at the output terminal approaching a voltage level corresponding to data to be output upon a change in level of the binary logic signal applied to said input terminal.

### BRIEF DESCRIPTION OF THE DRAWINGS

The present invention is described with the help of accompanying drawings in which.

FIG. 1 is a simplified diagrammatic view of an output buffer in accordance with the present invention.

FIG. 1A is a schematic diagram of a conventional driver.

FIG. 1B illustrates a plot of a pull up driver shown in FIG. 1A.

FIG. 2A is a schematic diagram of another conventional driver.

FIG. 2B illustrates a plot of a pull up driver shown in FIG. 2A.

FIG. 3 is a schematic diagram of a constant output buffer according to an embodiment of the present invention.

FIG. 4 is a schematic diagram of a constant output buffer according to another embodiment of the present invention.

FIG. 5 is a schematic diagram of a constant output buffer according to yet another embodiment of the present invention.

FIG. 6 illustrates a plot of a pull up buffer according to the present invention.

### DETAILED DESCRIPTION

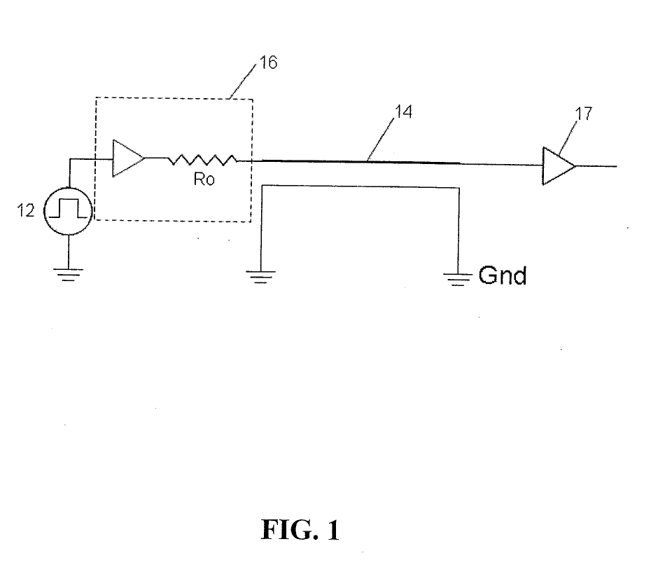

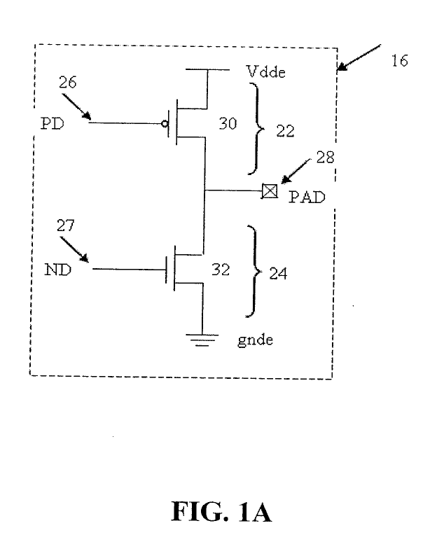

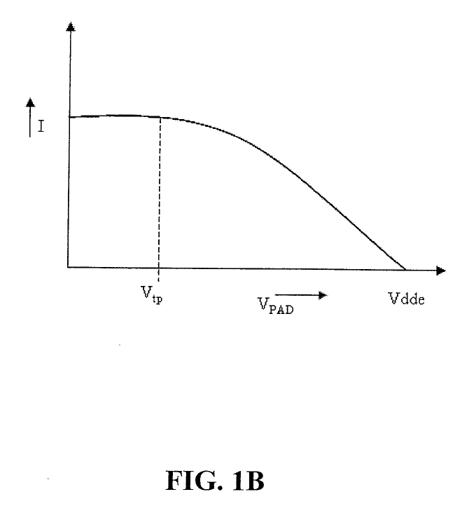

FIG. 1 shows an output buffer 16 according to the present invention. The output buffer 16 receives a signal from a signal source 12, and includes an output connected to the near end of the transmission line 14, whose far end is connected to the logic gate 17. The output buffer 16 can be employed in all types of integrated circuits including integrated logic circuits where this type of configuration is used. The output impedance of the buffer 16, designated Rₒ, is shown as constant impedance, in accordance with the present invention.

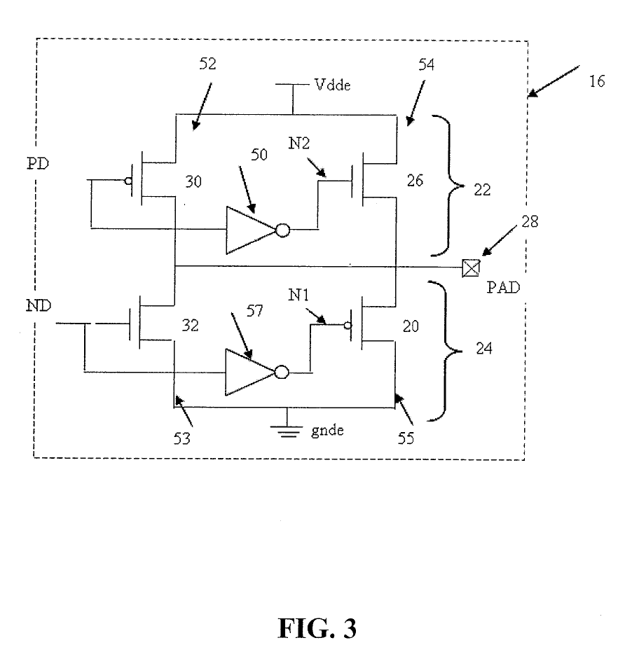

FIG. 3 is a schematic diagram of a constant output buffer according to an embodiment of the present invention. FIG. 3 shows a driver 16, which includes a supply node (Vdde, Gnde), an output pad node 28, and a pair of inputs PD and ND coupled to the pull up driver 22 and the pull down driver 24 respectively. The pull up driver 22 includes a normal branch 52 coupled to the supply node Vdde, an output pad node 28, a PD data signal and a parallel branch 54 coupled to the PD data signal through an inverting device 50, the supply node Vdde and the output pad node 28. Similarly, the pull down driver 24 consists of a normal branch 53 coupled to the supply node Gnde, the output pad node 28, the ND data signal and a parallel branch 55 coupled to the ND data signal through an inverting device 57, the supply node Gnde and the output pad node 28.

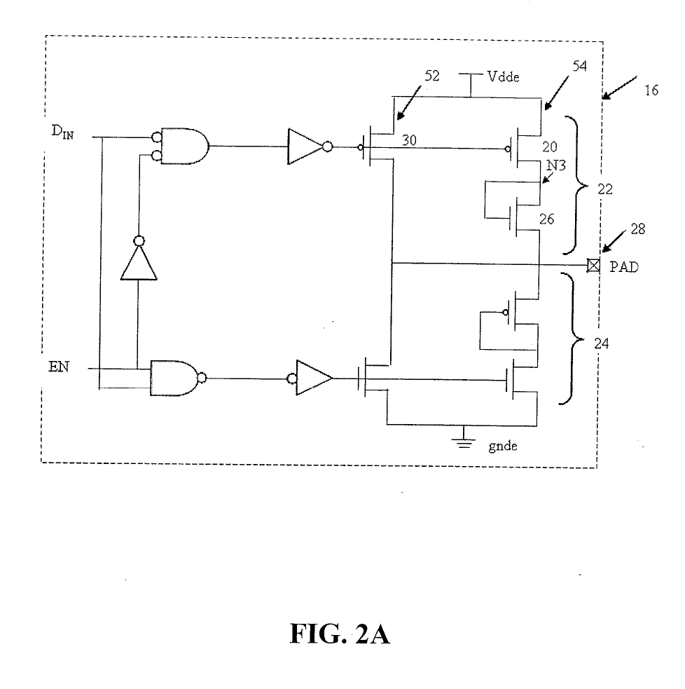

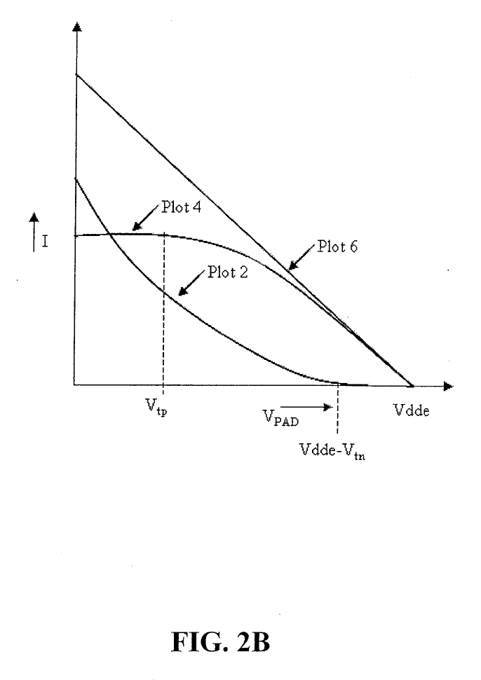

When an input data signal PD and ND go to a low state, the pull up driver 22 is enabled and the pull down driver 24 is disabled. The PD input signal of the normal branch 52 changes from a high level to a low level and at the same time node N2 of the parallel branch 54 changes from a low to a high logic. The current profile of the branch 52 is same as shown in plot 4 of FIG. 2B. Since the node N2 of branch 54 is at the supply logic level it's V_{GS} follows the voltage at node 28 and the current profile is same as shown in plot 2 of FIG. 2B. If we add these two current we will get almost linear current profile and thus the impedance of the pull up driver 22 would be almost constant. Since in the proposed architecture, the parallel branch 54 does not include series connected PMOS and NMOS transistors so a layout of the driver can be easily implemented with an optimized driver area.

A similar explanation can be given for the pull down driver 24.

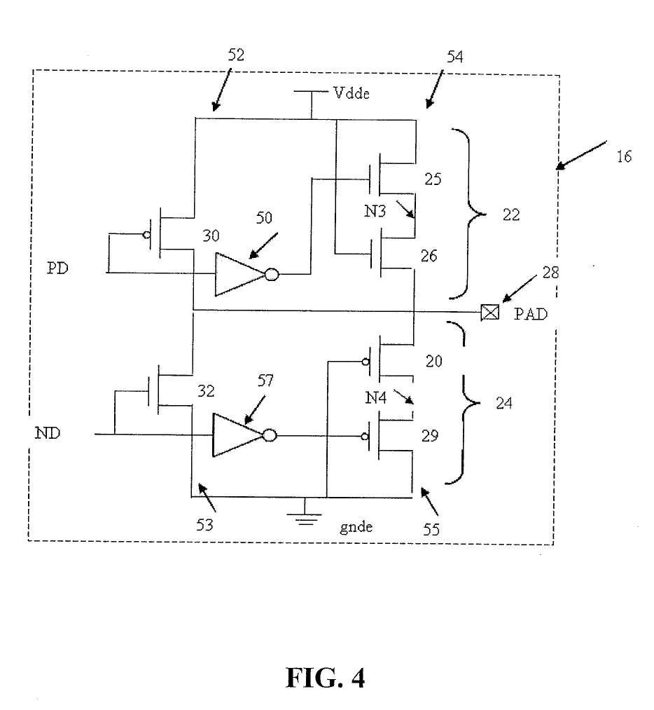

FIG. 4 is a schematic diagram of a constant output buffer according to another embodiment of the present invention. The buffer circuit shown in FIG. 4 differs from the output buffer circuit of FIG. 3 in that the parallel branch 54 of pull up driver 22, includes an NMOS switch 25 in series with an NMOS transistor 26. The NMOS transistor 26 is coupled with the supply node Vdde, the output pad node 28 and a node N3. The NMOS switch 25 is coupled with the supply node Vdde, the PD data signal through an inverting device 50 and the node N3. The gate to source voltage V_{GS} of the NMOS transistor 26 follow the output pad node 28 and give the similar current profile as shown in plot 2 of FIG. 2B. The NMOS transistor 25 is added to enable or disable the parallel branch 54 of the pull up driver 22. The normal branch 52 is same as in the proposed architecture. A similar explanation can be given for the pull down driver 24.

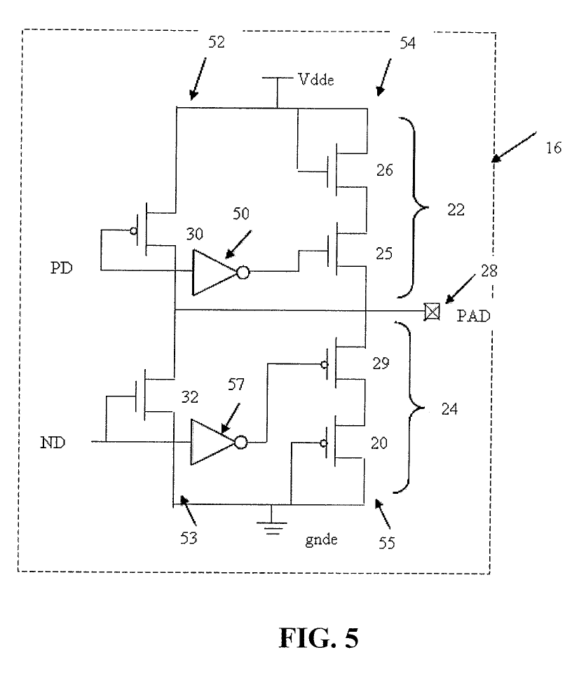

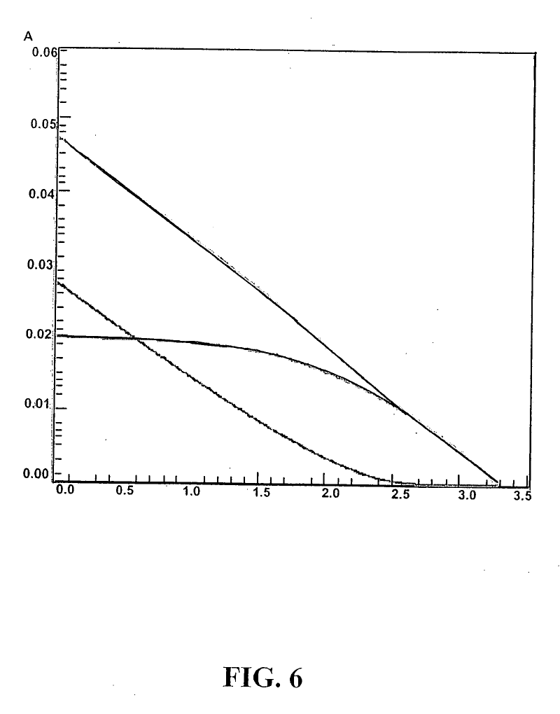

FIG. 5 is a schematic diagram of a constant output buffer according to yet another embodiment of the present invention. This diagram is an alternative embodiment of the present art shown in FIG. 4. The only difference in this embodiment is that the position of the NMOS switch 25 of FIG. 4 has been interchanged with the NMOS transistor 26 of FIG. 4. A complementary structure is implemented for the pull down driver 24. A plot of a pull up buffer is shown in the FIG. 6.

Having thus described at least one illustrative embodiment of the invention, various alterations, modifications, and improvements will readily occur to those skilled in the art. Such alterations, modifications, and improvements are intended to be within the scope of the invention. Accordingly, the foregoing description is by way of example only and is not intended as limiting. The invention is limited only as defined in the following claims and the equivalents thereto.

We claim:

1. A buffer circuit providing a constant impedance to a transmission line in an integrated circuit comprising:
an output terminal for outputting data;
an input terminal having a first terminal and a second terminal for receiving a binary logic signal;
a power supply terminal for providing a high potential;
a virtual voltage terminal for providing a low potential;
a first switching element connected between said output terminal and said power supply terminal, said first switching element comprising:
a first PMOS transistor having a gate terminal connected to said first terminal, a source terminal connected to said power supply terminal, and a drain terminal connected to said output terminal;
a second NMOS transistor having its gate terminal connected to said first terminal through an inverter, a drain terminal connected to said power supply terminal, and a source terminal connected to said output terminal;
a second switching element connected between said output terminal and said virtual voltage terminal, said second switching element comprising:
a third NMOS transistor having a drain terminal connected to said output terminal, a gate terminal connected to said second terminal, and a source terminal connected to said virtual voltage terminal;
a fourth PMOS transistor having a gate terminal connected to said second terminal through an inverter, a source terminal connected to the source of said second NMOS transistor, and a drain connected to said virtual voltage terminal;
switching control means for turning on and off said first and second switching elements in a complementary manner in response to said binary logic signal; and
compensating means for increasing output impedance to said output terminal in response to a voltage at said output terminal approaching a voltage level corresponding to the data to be output upon a change in level of said binary logic signal.

2. The buffer circuit as claimed in claim 1, wherein said compensating means comprises:
switching means coupled in parallel with at least one of said first and second switching elements, and
compensation control means responsive to the voltage at said output terminal for temporarily increasing impedance of said switching means upon a change in level of said binary logic signal.

3. A buffer circuit providing a constant impedance to a transmission line in an integrated circuit comprising:
an output terminal for outputting data;
an input terminal having a first terminal and a second terminal for receiving a binary logic signal;
a power supply terminal for providing a high potential;
a virtual voltage terminal for providing a low potential;
a first switching element connected between said output terminal and said power supply terminal, said first switching element comprising:
a first PMOS transistor having a gate terminal connected to said first terminal, its source terminal connected to said power supply terminal, and its drain terminal connected to said output terminal;
a second NMOS transistor having its gate terminal connected to said first terminal through an inverter, a drain terminal connected to said power supply terminal, and a source terminal connected to a potential terminal;
a third NMOS transistor having its gate terminal connected to said power supply terminal, a drain terminal connected to the source of said second transistor, and a source terminal connected to said output terminal;
a second switching element connected between said output terminal and said virtual voltage terminal, said second switching element comprising:
a fourth NMOS transistor having a drain terminal connected to said output terminal, a gate terminal connected to said second terminal, and a source terminal connected to said virtual voltage terminal;
a fifth PMOS transistor having a gate terminal connected to said virtual voltage terminal, a source terminal connected to the source of said third NMOS transistor, and a drain connected to a potential terminal;
a sixth PMOS transistor having a gate terminal connected to said second terminal through an inverter, a source terminal connected to the drain terminal of said fifth transistor, and a drain terminal connected to said virtual voltage terminal;
switching control means for turning on and off said first and second switching elements in a complementary manner in response to said binary logic signal; and
compensating means for increasing output impedance to said output terminal in response to a voltage at said output terminal approaching a voltage level corresponding to the data to be output upon a change in level of said binary logic signal.

4. The buffer circuit as claimed in claim 3, wherein said compensating means comprises:
switching means coupled in parallel with at least one of said first and second switching elements, and
compensation control means responsive to the voltage at said output terminal for temporarily increasing impedance of said switching means upon a change in level of said binary logic signal.

5. A buffer circuit providing a constant impedance to a transmission line in an integrated circuit comprising:
an output terminal for outputting data;
an input terminal having a first terminal and a second terminal for receiving a binary logic signal;
a power supply terminal for providing a high potential;
a virtual voltage terminal for providing a low potential;
a first switching element connected between said output terminal and said power supply terminal, said first switching element comprising:
a first PMOS transistor having a gate terminal connected to said first terminal, a source terminal connected to said power supply terminal, and a drain terminal connected to said output terminal;
a second NMOS transistor having a gate terminal and a drain terminal connected to said power supply terminal, and a source terminal connected to a potential terminal;
a third NMOS transistor having its gate terminal connected to said first terminal through an inverter, a drain terminal connected to the source of said second NMOS transistor through said potential terminal, and a source terminal connected to said output terminal;
a second switching element connected between said output terminal and said virtual voltage terminal, said second switching element comprising:
a fourth NMOS transistor having a drain terminal connected to said output terminal, a gate terminal connected to said second terminal, and a source terminal connected to said virtual voltage terminal;
a fifth PMOS transistor having a gate terminal connected to said second terminal through an inverter, a source connected to the source of said third NMOS transistor, and a drain connected to a potential terminal;
a sixth PMOS transistor having a gate terminal and a drain terminal connected to said virtual voltage terminal, and a source terminal connected to the drain terminal of said fifth transistor through said potential terminal;
switching control means for turning on and off said first and second switching elements in a complementary manner in response to said binary logic signal; and
compensating means for increasing output impedance to said output terminal in response to a voltage at said output terminal approaching a voltage level corresponding to the data to be output upon a change in level of said binary logic signal.

6. The buffer circuit as claimed in claim 5, wherein said compensating means comprises:
switching means coupled in parallel with at least one of said first and second switching elements, and
compensation control means responsive to the voltage at said output terminal for temporarily increasing impedance of said switching means upon a change in level of said binary logic signal.

7. A method of providing a constant output impedance to a transmission line in an integrated circuit through a buffer circuit comprising:
connecting an output terminal to a first power supply terminal through a first switching element, when a first logic level signal is applied to an input terminal;
connecting said output terminal to a second power supply terminal through a second switching element, when a second logic level signal is applied to said input terminal; and
increasing impedance in series with said output terminal in response to a voltage at the output terminal approaching a voltage level corresponding to data to be output upon a change in level of the binary logic signal applied to said input terminal.
